(19) United States
(12) Patent Application Publication
(10) Pub. No.: US 2026/0339149 A1
(43) Pub. Date: Oct. 29, 2026

(54) SUBSTRATE ASSEMBLY AND DISPLAY DEVICE INCLUDING THE SAME

(71) Applicant: SEOUL SEMICONDUCTOR CO., LTD., Ansan-si (KR)

(72) Inventors: Mi So KO, Ansan-si (KR); Eun Mi CHOI, Ansan-si (KR)

(73) Assignee: SEOUL SEMICONDUCTOR CO., LTD., Ansan-si (KR)

(21) Appl. No.: 19/192,136

(22) Filed: Apr. 28, 2025

Related U.S. Application Data
(60) Provisional application No. 63/642,071, filed on May 3, 2024.

(51) Int. Cl. G02F 1/13357

(52) U.S. Cl. CPC G02F 1/133608; G02F 1/133603; G02F 1/133605; G02F 1/133606

(57) ABSTRACT

According to an aspect of the present disclosure, there may be provided a substrate assembly including: a first substrate having a plurality of grooves formed on one surface; and a second substrate extending in one direction to support a plurality of light emitting devices and supported on the one surface of the first substrate. The plurality of grooves include: a first groove extending in a direction parallel to the one direction; and a second groove extending in a direction deviating from the first groove.

### CROSS-REFERENCE TO RELATED APPLICATIONS

The present application claims the benefit of priority to U.S. Provisional Application No. 63/642,071 filed May 3, 2024, which is incorporated herein by reference in its entirety.

### TECHNICAL FIELD

The present disclosure relates to a substrate assembly and a display device including the same.

### BACKGROUND OF INVENTION

A display is a device that shows characters, symbols, images, or videos. A display may include a light emitting device that emits light and a liquid crystal that adjusts the light emitted from the light emitting device.

The light emitting device includes a light emitting surface, and for the characters, symbols, images, or videos displayed on the screen to be shown more clearly, the light must be emitted evenly across the entire light emitting surface. In other words, the higher the surface light emission efficiency of the light emitting device, the clearer the characters, symbols, images, or videos displayed on the screen will appear. Such a light emitting device can generate heat when emitting light.

However, conventional displays have the problem that, since fluid cannot flow inside, heat generated by the light emitting device cannot be dissipated efficiently.

### CONTENTS OF INVENTION

### Problems to be Solved by Invention

Embodiments of the present disclosure are developed based on the above background, and provide a substrate assembly with grooves formed for dissipating heat from the light emitting device, and a display device including the same.

### Means for Solving Problems

In accordance with one aspect of the present disclosure, there may be provided a substrate assembly including: a first substrate having a plurality of grooves formed on one surface; and a second substrate extending in one direction to support a plurality of light emitting devices and supported on the one surface of the first substrate, wherein the plurality of grooves include: a first groove extending in a direction parallel to the one direction; and a second groove extending in a direction deviating from the first groove.

Further, there may be provided the substrate assembly in which the second groove partially overlaps with the second substrate in a thickness direction of the second substrate. Herein, the term “overlap in the thickness direction of the second substrate” is to be understood so that, in the area of the overlap, a straight line in a thickness direction of the second substrate would pass through both the second substrate and the groove.

Further, there may be provided the substrate assembly in which the second substrate includes: a contact region in contact with the first substrate; and an overlapping region overlapping with the second groove in the thickness direction of the second substrate, and wherein an area of the contact region is larger than an area of the overlapping region.

Further, there may be provided the substrate assembly in which the second substrate is supported on the first substrate such that the contact region and the overlapping region alternate in the one direction.

Further, there may be provided the substrate assembly in which each of the plurality of grooves includes: a groove bottom surface; and a plurality of groove side surfaces inclined with respect to the groove bottom surface, and wherein the groove bottom surface is disposed between the plurality of groove side surfaces.

Further, there may be provided the substrate assembly in which a thickness of the first substrate and a thickness of the second substrate are different from each other.

Further, there may be provided the substrate assembly in which the plurality of grooves further includes a curved groove connecting the first groove and the second groove.

Further, there may be provided the substrate assembly in which the plurality of grooves further includes a third groove extending in a direction different from the first groove and the second groove.

Further, there may be provided the substrate assembly in which the second groove includes a plurality of second grooves, and wherein a width of one of the plurality of second grooves is different from a width of another one of the plurality of second grooves.

Further, there may be provided the substrate assembly in which the second groove includes a plurality of second grooves, and wherein a depth of one of the plurality of second grooves is different from a depth of another one of the plurality of second grooves.

Further, there may be provided the substrate assembly in which the second substrate includes a plurality of second substrates, and wherein an area of the overlapping region of one of the plurality of second substrates is different from an area of the overlapping region of another one of the plurality of second substrates.

Further, there may be provided the substrate assembly in which one or more holes are formed in at least one of the first substrate and the second substrate.

Further, there may be provided the substrate assembly in which the first substrate includes: a main body for supporting the second substrate; and a plurality of inclined portions disposed at an edge of the main body and inclined with respect to the main body, and wherein the plurality of inclined portions include: a plurality of first side inclined portions disposed at the edge of the main body and spaced apart from each other in the one direction; and a plurality of second side inclined portions disposed at the edge of the main body and spaced apart from each other in another direction perpendicular to the one direction, and wherein the first side inclined portion and the second side inclined portion are inclined at different angles with respect to the main body.

Further, there may be provided the substrate assembly in which the plurality of inclined portions further include: an auxiliary inclined portion disposed between the first side inclined portion and the second side inclined portion and inclined at an angle different from the angles of the first side inclined portion and the second side inclined portion.

Further, there may be provided a substrate assembly including: a first substrate having a plurality of grooves formed on one surface; and a second substrate extending in one direction to support a plurality of light emitting devices and supported on the one surface of the first substrate, wherein the plurality of grooves includes: a groove portion extending in a direction perpendicular to the one direction; and an extension groove extending in a direction deviating from the groove portion.

Further, there may be provided a display device including: a plurality of light emitting devices that generate light; a substrate assembly supporting the plurality of light emitting devices; and a reflective sheet supported on the substrate assembly and reflecting the light emitted from the plurality of light emitting devices, wherein the substrate assembly includes: a first substrate having a plurality of grooves formed on one surface; and a second substrate extending in one direction to support the plurality of light emitting devices and supported on the one surface of the first substrate, and at least some of the plurality of grooves extend in different directions.

Further, there may be provided the display device in which the second substrate includes: a plurality of device regions in which the plurality of light emitting devices are respectively disposed; and a pattern region located between the plurality of device regions and having one or more patterns with a reflectance different from a surface of the second substrate.

Further, there may be provided the display device in which the reflective sheet includes a plurality of holes, and wherein at least one of the plurality of holes is formed at a position where one or more patterns in the pattern region are exposed to an outside.

Further, there may be provided the display device further including: a diffusion sheet diffusing light emitted from the plurality of light emitting devices; and a spacer disposed between the reflective sheet and the diffusion sheet, wherein the spacer reflects light emitted from the plurality of light emitting devices.

Further, there may be provided the display device further including: a controller supported on another surface opposite to the one surface of the first substrate and configured to control the plurality of light emitting devices; and a bridge line electrically connecting the controller and the plurality of light emitting devices, wherein the first substrate includes a second hole through which the bridge line passes, and wherein the plurality of grooves include: a plurality of groove portions extending in a direction perpendicular to the one direction and spaced apart from each other in the one direction, and wherein the second hole is located between the plurality of groove portions.

### Effects of Invention

An embodiment of the display device according to the present disclosure has the effect of efficiently dissipating heat from the light emitting device through a groove in which a fluid flows.

In addition, the display device is configured such that the degree of light reflection increases toward an edge, which has the effect of enhancing the surface light emitting effect.

### BRIEF DESCRIPTION OF DRAWINGS

FIG. 1 is a view illustrating a display device according to a first embodiment of the present disclosure.

FIG. 2 is a plan view showing a substrate assembly of the display device of FIG. 1, with a reflection sheet attached.

FIG. 3 is a plan view of the substrate assembly of the display device of FIG. 1, with the reflection sheet detached.

FIG. 4 is an enlarged view of portion X of the display device of FIG. 1.

FIG. 5 illustrates a view where a first curved surface is further included in the groove of FIG. 4.

FIG. 6 shows the groove of FIG. 5 with the first curved surface forming a furrow.

FIG. 7 shows the groove of FIG. 4 formed asymmetrically.

FIG. 8 illustrates a view where a first curved surface, a second curved surface, a third curved surface, and a fourth curved surface are further included in the groove of FIG. 4.

FIG. 9 shows the groove of FIG. 8 with the first and second curved surfaces having a concave shape.

FIG. 10 shows a light emitting device of the display device of FIG. 1.

FIG. 11 is a plan view of a substrate assembly of a display device according to a second embodiment of the present disclosure.

FIG. 12 is a plan view of a substrate assembly of a display device according to a third embodiment of the present disclosure.

FIG. 13 is a plan view of a reflection sheet of the display device of FIG. 12.

FIG. 14 is a perspective view of a second substrate including a device region and a pattern region of the display device of FIG. 12.

FIG. 15 is a perspective view showing the substrate assembly and reflection sheet of the display device of FIG. 12, with the pattern region exposed to an outside.

FIG. 16 is a perspective view of the substrate assembly, the reflection sheet, and a spacer of the display device of FIG. 12.

### SPECIFIC CONTENTS FOR EMBODYING INVENTION

Hereinafter, specific embodiments for implementing a spirit of the present disclosure will be described in detail with reference to the drawings.

In describing the present disclosure, detailed descriptions of known configurations or functions may be omitted to clarify the present disclosure.

When an element is referred to as being ‘connected’ to, ‘supported’ by, or ‘coupled’ with another element, it should be understood that the element may be directly connected to, supported by, or coupled with another element, but that other elements may exist in the middle.

The terms used in the present disclosure are only used for describing specific embodiments, and are not intended to limit the present disclosure. Singular expressions include plural expressions unless the context clearly indicates otherwise.

Terms including ordinal numbers, such as first and second, may be used for describing various elements, but the corresponding elements are not limited by these terms. These terms are only used for the purpose of distinguishing one element from another element.

In the present specification, it is to be understood that the terms such as “including” are intended to indicate the existence of the certain features, areas, integers, steps, actions, elements, combinations, and/or groups thereof disclosed in the specification, and are not intended to preclude the possibility that one or more other certain features, areas, integers, steps, actions, elements, combinations, and/or groups thereof may exist or may be added.

Further, in the present disclosure, it is to be noted that expressions, such as the upper surface and the lower surface, are described based on the illustration of drawings, but may be modified if directions of corresponding objects are changed.

Hereinafter, specific configurations of a display device 1 according to a first embodiment of the present disclosure with reference to the drawings.

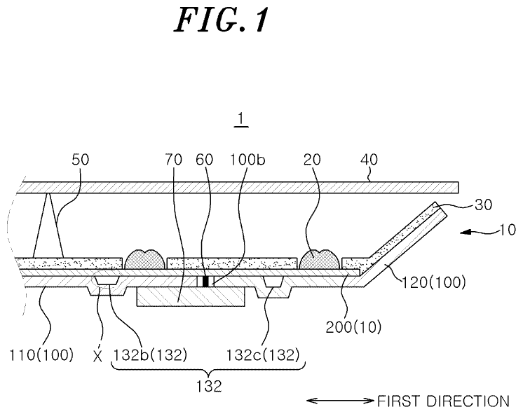

Referring to FIGS. 1 to 3, the display device 1 is capable of displaying characters, symbols, images, or video. The display device 1 may include a substrate assembly 10, a light emitting device 20, a reflective sheet 30, a diffusion sheet 40, a spacer 50, a bridge line 60, and a controller 70.

The substrate assembly 10 can support the light emitting device 20 and the reflective sheet 30. Additionally, the substrate assembly 10 may provide the outer shape of the display device 1. The substrate assembly 10 may include a first substrate 100 and a second substrate 200.

The first substrate 100 can support the second substrate 200 and the controller 70. In other words, one surface of the first substrate 100 may support the second substrate 200, while another surface, opposite to the one surface, may support the controller 70. The first substrate 100 may be a thermally conductive substrate. One surface of the first substrate 100 may be an inner surface, and the other surface may be an outer surface. The thickness of the first substrate 100 and the second substrate 200 may be formed differently. The thickness of the first substrate 100 may be greater or smaller than that of the second substrate 200. Furthermore, the thermal conductivity, light reflectivity, and area of the first substrate 100 and the second substrate 200 may be different. The thermal conductivity of the first substrate 100 may be greater than that of the second substrate 200. Alternatively or additionally, the area of the first substrate 100 may be larger than that of the second substrate 200. The light reflectivity of the first substrate 100 may differ from that of the second substrate 200. The first substrate 100 may include a main body 110 and a plurality of inclined portions 120.

The main body 110 can support the second substrate 200 and the inclined portion 120. In other words, one surface or one side of the main body 110 may be provided with the second substrate 200, while an edge of the main body 110 may be provided with the inclined portion 120. Additionally, the main body 110 may include a hole formed therein. The hole may be formed as one or more holes. The hole may include at least one of a first hole 110a and a second hole 110b.

The first hole 110a allows a fluid to pass through. Through the first hole 110a, the fluid can flow from an outer side to an inner side of the first substrate 100, or from the inner side to the outer side of the first substrate 100. Therefore, heat dissipation through the surface area formed by the first hole 110a is possible, and the cooling effect from the fluid can be increased. The first hole 110a may be formed as a plurality of holes. The sizes of at least two first holes 110a may be formed differently from each other. At least one of the plurality of first holes 110a may be formed between a first groove portion 132a and a second groove portion 132b, as will be described later. Alternatively, at least one of the plurality of first holes 110a may be disposed in the second groove portion 132b.

Additionally, a thermally conductive material may pass through the first hole 110a. Through the first hole 110a, the thermally conductive material can pass from the inner side to the outer side of the first substrate 100. Therefore, the heat dissipation efficiency of the first substrate 100 can be increased by the thermally conductive material. The thermally conductive material may include a metal material and may protrude beyond the surface of the first substrate 100.

The second hole 110b provides a passage for the bridge line 60. Through the second hole 110b, the bridge line 60 may be connected between the second substrate 200 and the controller 70. The second hole 110b may be positioned between the second groove portion 132b and a third groove portion 132c, as will be described later, and arranged closer to the second groove portion 132b than to the third groove portion 132c.

The plurality of inclined portions 120 are disposed around or along the edges of the main body 110 and may be arranged to be inclined with respect to the main body 110. The plurality of inclined portions 120 may be arranged to incline towards the diffusion sheet 40 as they are farther from the main body 110. In other words, the height of the inclined portions 120 may increase as they are farther from the main body 110. Therefore, the plurality of inclined portions 120 can reduce the decrease in the amount of light entering the diffusion sheet 40 as the plurality of inclined portions move away from the light emitting device 20.

Further, at least some of the plurality of inclined portions 120 may be formed to incline at different angles with respect to the main body 110. The plurality of inclined portions 120 may include a first side inclined portion 121, a second side inclined portion 122, and optionally, an auxiliary inclined portion 123.

The first side inclined portion 121 is formed as a plurality and may be arranged on both sides of the main body 110 to be spaced apart in one direction (first direction). In other words, the first side inclined portion 121 may be arranged to incline with respect to the main body 110 to form a predetermined first angle.

The second side inclined portion 122 is formed as a plurality and may be arranged on both sides of the main body 110 to be spaced apart in the other direction (second direction) perpendicular to one direction. The second side inclined portion 122 and the first side inclined portion 121 may be arranged at different inclinations with respect to the main body 110. In other words, the second side inclined portion 122 may be arranged to incline with respect to the main body 110 to form a second angle, which may be different from the first angle. Additionally, the length of the second side inclined portion 122 in the other direction may be shorter than the length of the first side inclined portion 121 in the one direction. Therefore, the light emitted from the light emitting device 20 can be reflected at various angles, increasing the uniformity of the light entering the diffusion sheet 40.

The auxiliary inclined portion 123 may be arranged between the first side inclined portion 121 and the second side inclined portion 122. The auxiliary inclined portion 123 may be formed as a plurality. One of the plurality of auxiliary inclined portions 123 may be arranged between one of the plurality of first side inclined portions 121 and one of the plurality of second side inclined portions 122. Additionally, another of the plurality of auxiliary inclined portions 123 may be arranged between another of the plurality of first side inclined portions 121 and the one of the plurality of second side inclined portions 122. Moreover, the two sides of another of the plurality of second side inclined portions 122 may be connected to the first side inclined portion 121.

Further, the auxiliary inclined portion 123 may be arranged to be inclined with respect to the main body 110 at a different inclination from at least one of the first side inclined portion 121 and the second side inclined portion 122.

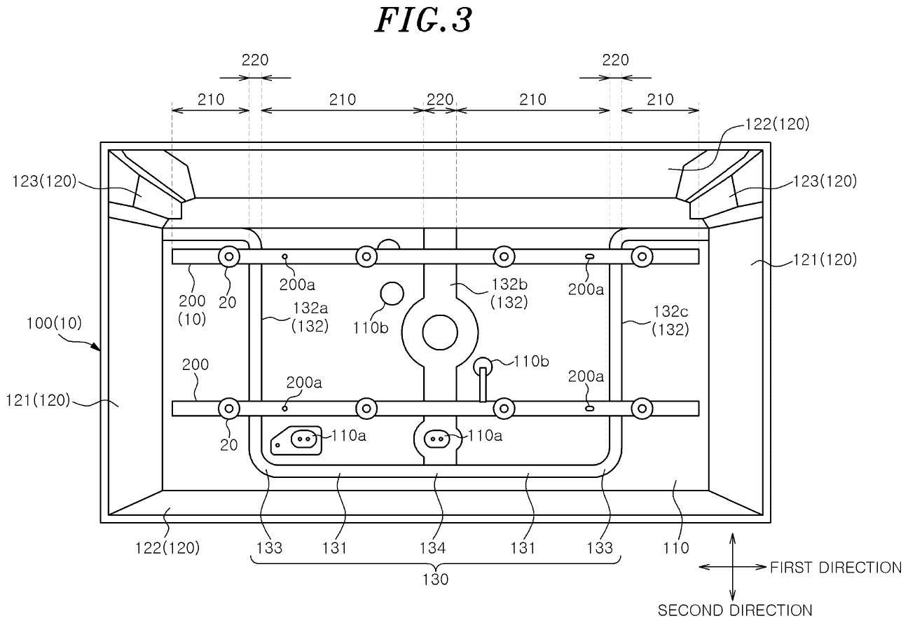

Referring to FIG. 3, the first substrate 100 may include a plurality of grooves 130. The plurality of grooves 130 may be formed on one surface of the first substrate 100. The plurality of grooves 130 may provide a space for a fluid to be placed or a passage for a fluid to be flow. The fluid may include air. Some of the plurality of grooves 130 may extend in different directions. Therefore, it is possible to form a flow path across a wide area of the first substrate 100. Further, at least some of the plurality of grooves 130 may be in communication with each other.

At least some of the plurality of grooves 130 may have different widths. The width may be the length in the direction perpendicular to the direction in which each of the plurality of grooves 130 extends. Further, at least some of the plurality of grooves 130 may have different depths. The depth is the length in the direction perpendicular to the surface of the first substrate 100.

The plurality of grooves 130 may include a first groove 131, a second groove 132, a curved groove 133, and a branching groove 134.

The first groove 131 may extend in a direction parallel to the one direction. In other words, the first groove 131 may extend in the same direction as the length direction of the second substrate 200. The first groove 131 may be referred to as a parallel groove. Further, the first groove 131 may be formed as a plurality of grooves, arranged in a direction perpendicular to the one direction, spaced apart from each other.

The second groove 132 may extend in a direction different from the one direction. The second groove 132 may extend in a direction perpendicular to the one direction. The second groove 132 may be referred to as a groove portion. When viewed towards one surface of the first substrate 100, the second groove 132 may be arranged such that a part thereof overlaps with the second substrate 200. The fluid may flow between the first substrate 100 and the second substrate 200 through the second groove 132. Further, the second groove 132 may be formed as a plurality of grooves, spaced apart from each other in the one direction. At least some of the plurality of second grooves 132 may overlap with the second substrate 200. Furthermore, the width and depth of any one of the plurality of second grooves 132 may differ from the width and depth of another of the second grooves 132.

The plurality of second grooves 132 may include a first groove portion 132a, a second groove portion 132b, and a third groove portion 132c. The second groove portion 132b may be disposed between the first groove portion 132a and the third groove portion 132c. In other words, the second groove portion 132b may be positioned closer to a center of the second substrate 200 than the first groove portion 132a and the third groove portion 132c. The width of the second groove portion 132b may be larger than the width of the first groove portion 132a and the third groove portion 132c. Further, the depth of the second groove portion 132b may be smaller than the depth of the first groove portion 132a and the third groove portion 132c. The depth of the first groove portion 132a and the third groove portion 132c may be the same as the depth of the first groove 131.

The curved groove 133 may be formed with a predetermined curvature, connecting the first groove 131 and the second groove 132. The curved groove 133 may allow communication between one side of the first groove 131 and one side of the second groove 132.

The branching groove 134 may be connected to a plurality of grooves 140. The branching groove 134 may be connected to a plurality of first grooves 131 and a plurality of second grooves 132. For example, the branching groove 134 may connect the second groove portion 132c to the plurality of first grooves 131.

The first groove 131, the second groove 132, the curved groove 133, and the branching groove 134 may be connected with each other to form a single connecting groove. In other words, the first groove 131, the curved groove 133, the first groove portion 132a, the curved groove 133, the first groove 131, the branching groove 134, the first groove 131, the curved groove 133, the third groove portion 132c, the curved groove 133, and the first groove 131 may be sequentially connected, and the second groove portion 132b may be connected to the branching groove 134, forming a single connecting groove.

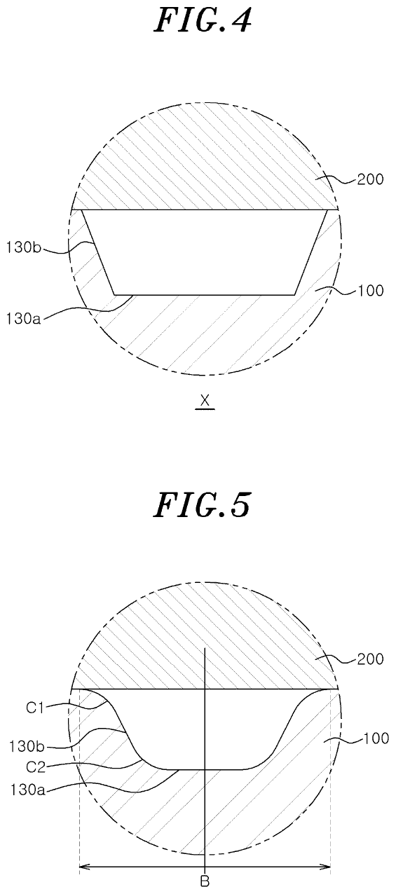

Referring to FIG. 4, the groove 130 may include a groove bottom surface 130a and a groove side surface 130b.

The groove side surface 130b may connect the groove bottom surface 130a and one surface of the first substrate 100, and may be arranged at an inclined angle with respect to the groove bottom surface 130a. In other words, the groove side surface 130b is connected at one side to the groove bottom surface 130a, while the other side opposite to the one side is connected to the one surface of the first substrate 100, and the other side may be tilted to be positioned further outward from the groove bottom surface 130a than the one side. Since the groove side surface 130b is inclined relative to the groove bottom surface 130a, the width of the groove 130 may increase, thereby improving heat dissipation efficiency. The vertical distance from the groove side surface 130b to the bottom surface of the second substrate 200 may increase as it approaches the groove bottom surface 130a.

FIG. 5 is a modified embodiment of FIG. 4. Referring to FIG. 5, the groove 130 may additionally include a first curved surface C1 and a second curved surface C2, in addition to those previously described. The first curved surface C1 may be included in a portion where the groove bottom surface 130a and the groove side surface 130b connect. Further, the second curved surface C2 may be included in a portion where the groove side surface 130b and one surface of the first substrate 100 connect. The curvature of the first curved surface C1 and the second curved surface C2 may be different from each other. As a result, the first curved surface C1 and the second curved surface C2 may form a smooth flow path, allowing fluid to diffuse smoothly. At least a portion of the groove side surface 130b between the first curved surface C1 and the second curved surface C2 may include a flat surface. The groove 130 may be symmetric with respect to a central point B of the groove 130.

FIG. 6 is a modified embodiment of FIGS. 4 and 5. Referring to FIG. 6, in addition to the previously described, the first curved surface C1 may be recessed below the upper surface of the groove bottom surface 130a to form a furrow. Therefore, the first curved surface C1 may form a furrow. Alternatively, the first curved surface C1 may be recessed relative to the upper surface of the groove bottom surface 130a to form a furrow. The furrow portion may be disposed on either side of the groove bottom surface 130a or on both sides thereof. Since the first curved surface C1 may include the furrow portion, the surface area of the groove 130 may be increased.

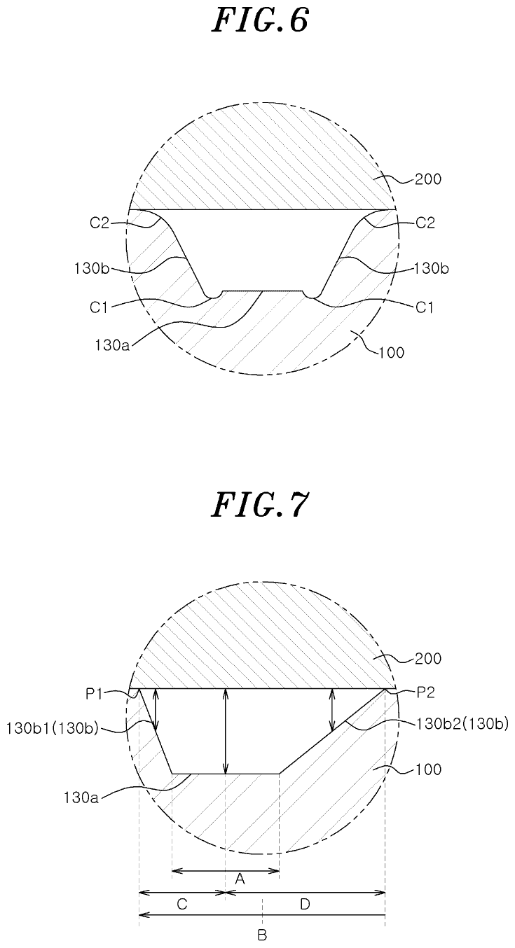

FIG. 7 is a modified embodiment of FIGS. 4 to 6. Referring to FIG. 7, in addition to the previously described, the groove bottom surface 130a may be positioned offset to one side within the region where the groove 130 is formed. As a result, the inclination of the first groove side surface 130b1, formed on one side of the groove bottom surface 130a, may differ from the inclination of the second groove side surface 130b2, formed on the other side opposite to the one side. The inclination of the first groove side surface 130b1 may be greater than that of the second groove side surface 130b2. The horizontal distance C from the first point P1, where the first groove side surface 130b1 connects to one surface of the first substrate 200, to the central point A of the groove bottom surface 130a, may be smaller than the horizontal distance D from the second point P2, where the second groove side surface 130b2 connects to one surface of the first substrate 100, to the central point A of the groove bottom surface 130a. Further, the surface length from the first point P1 to the central point A of the groove bottom surface 130a may be smaller than the surface length from the second point P2, where the second groove side surface 130b2 connects to one surface of the first substrate 100, to the central point A of the groove bottom surface 130a. When viewed in cross section, the central point A of the groove bottom surface 130a may be vertically offset from the central point B between the first point P1 and the second point P2. The two sides may be asymmetric with respect to the central point B. As a result, a wider flow space can be secured while increasing the surface area of the groove.

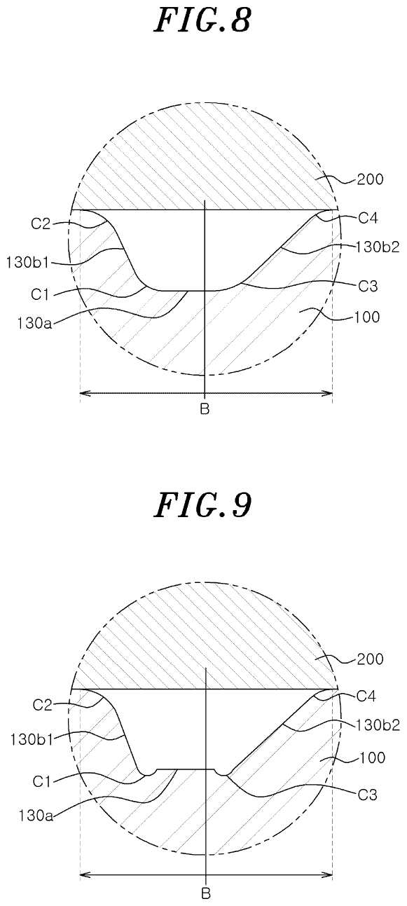

FIG. 8 is a modified embodiment of FIGS. 4 to 7. Referring to FIG. 8, in addition to the previously explained details, the groove 130 may include a first curved surface C1, a second curved surface C2, a third curved surface C3, and a fourth curved surface C4. The first curved surface C1 may be included in a portion where the groove bottom surface 130a and the first groove side surface 130b1 connect. The second curved surface C2 may be included in a portion where the first groove side surface 130b1 and one surface of the first substrate 100 connect. The curvature of the first curved surface C1 and the curvature of the second curved surface C2 may be different from each other. The third curved surface C3 may be included in a portion where the groove bottom surface 130a and the second groove side surface 130b2 connect. The fourth curved surface C4 may be included in a portion where the second groove side surface 130b2 and one surface of the first substrate 100 connect. The curvature of the third curved surface C3 and the curvature of the fourth curved surface C4 may also differ from each other. Alternatively, the curvature of the first curved surface C1 and the curvature of the third curved surface C3 may differ. Or, the curvature of the second curved surface C2 and the curvature of the fourth curved surface C4 may differ. Thus, a smooth flow path can be formed, allowing fluid to diffuse smoothly. At least part of the first groove side surface 130b1 between the first curved surface C1 and the second curved surface C2, or part of the second groove side surface 130b2 between the third curved surface C3 and the fourth curved surface C4, may include a flat surface. The shapes on both sides of the central point B may be asymmetrical.

FIG. 9 is a modified embodiment of FIGS. 4 to 8. Referring to FIG. 9, in addition to the previously explained details, the first curved surface C1 may be recessed below the upper surface of the groove bottom surface 130a to form a furrow. Therefore, the first curved surface C1 may include a furrow portion. Alternatively or additionally, the third curved surface C3 may be recessed below the upper surface of the groove bottom surface 130a to form a furrow. Thus, the third curved surface C3 may include a furrow portion. The furrow portion may be disposed on one side or both sides of the groove bottom surface 130a. The first curved surface C1 or the third curved surface C3, including the furrow portion, can increase the surface area of the groove 130.

Referring again to FIG. 3, the second substrate 200 may extend in one direction to be disposed on one surface of the first substrate 100 to support a plurality of light emitting devices 20. The plurality of light emitting devices 20 may be disposed on one surface of the second substrate 200. The second substrate 200 may be a circuit board. The thickness of the second substrate 200 and the thickness of the first substrate 100 may differ. For example, the thickness of the first substrate 100 may be greater than that of the second substrate 200. A hole 200a may be formed in the second substrate 200. A fluid may be disposed in the hole 200a and may fill or penetrate the hole 200a.

Furthermore, the second substrate 200 may be formed as a single piece, or it may be formed in multiple pieces and arranged spaced apart in different directions. The second substrate 200 may extend in one direction and be positioned to overlap with one or more second grooves 132. In other words, the second substrate 200 may be supported on the first substrate 100 to overlap with the first groove portion 132a, second groove portion 132b, and third groove portion 132c. The second substrate 200 may include a contact region 210 and an overlapping region 220. Meanwhile, the contact region 210 and the overlapping region 220 may be disposed on the other surface opposite to the one surface of the second substrate 200.

The contact region 210 may be an area where the second substrate 200 is connected to or contacts the first substrate 100. The contact region 210 may include a plurality of contact regions. Further, at least one hole 200a in the second substrate 200 may be disposed to vertically overlap with the contact region 210. Furthermore, at least one light emitting device 20 may be disposed in the contact region 210. Thus, the heat dissipation efficiency can be increased.

The overlapping region 220 may be an area in the second substrate 200 that overlaps with the second groove 132 when viewed towards one surface of the first substrate 100. In other words, a fluid may be disposed or flow between the overlapping region 220 and the second groove 132. The fluid may be air. The second substrate 200 may be supported on the first substrate 100 such that the contact region 210 and the overlapping region 220 are alternately disposed on a lower portion of the second substrate 200. In other words, the overlapping region 220 may be disposed between the plurality of contact regions 210. Further, the area of the contact region 210 on the second substrate 200 may be larger than the area of the overlapping region 220.

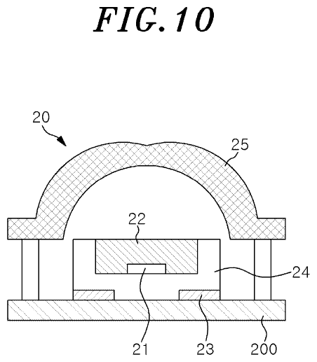

Referring further to FIG. 10, the light emitting device 20 may be formed in a plurality of light emitting devices to generate light. The plurality of light emitting devices 20 may be supported on the second substrate 200 and disposed to extend in one direction from one another. The light emitting device 20 may include a light emitting diode chip 21, a molding portion 22, an electrode 23, a housing 24, and a lens 25.

The light emitting diode chip 21 is disposed inside the housing 24 and may include a P-type semiconductor and an N-type semiconductor. The P-type semiconductor may be connected to the positive terminal of a power supply through the second substrate 200. The N-type semiconductor may be connected to the negative terminal of the power supply through the second substrate 200. Additionally, when electricity is supplied to the P-type semiconductor and the N-type semiconductor of the light emitting diode chip 21, the light emitting diode chip 21 can emit light.

The molding portion 22 may be disposed inside the housing 24 and may cover the light emitting diode chip 21. The molding portion 22 may cover the light emitting diode chip 21 to seal it from the outside, thereby protecting the light emitting diode chip 21. Additionally, the molding portion 22 may contain phosphor.

The electrode 23 can electrically connect the light emitting device 20 and the second substrate 200 to allow light emission from the light emitting device 20. The electrode 23 is disposed on the lower side of the housing 24 and can be connected to the second substrate 200.

In the housing 24, the light emitting diode chip 21 and the molding portion 22 may be disposed. In other words, the housing 24 may provide space inside to accommodate the light emitting diode chip 21 and the molding portion 22. For example, the housing 24 may be formed from common plastics such as those including polymers, epoxy, silicone, ABS (acrylonitrile butadiene styrene), LCP (liquid crystalline polymer), PA (polyamide), IPS (polyphenylene sulfide), or TPE (thermoplastic elastomer), or may be made of metal or ceramic.

The lens 25 may cover the housing 24 to allow light emitted from the light emitting diode chip 21 to pass through. The lens 25 may direct the light emitted from the light emitting diode chip 21. Additionally, the upper surface of the lens 25, where the light exits, may include a convex surface and a concave surface facing the housing 24. The concave surface can be located at the center of the upper surface.

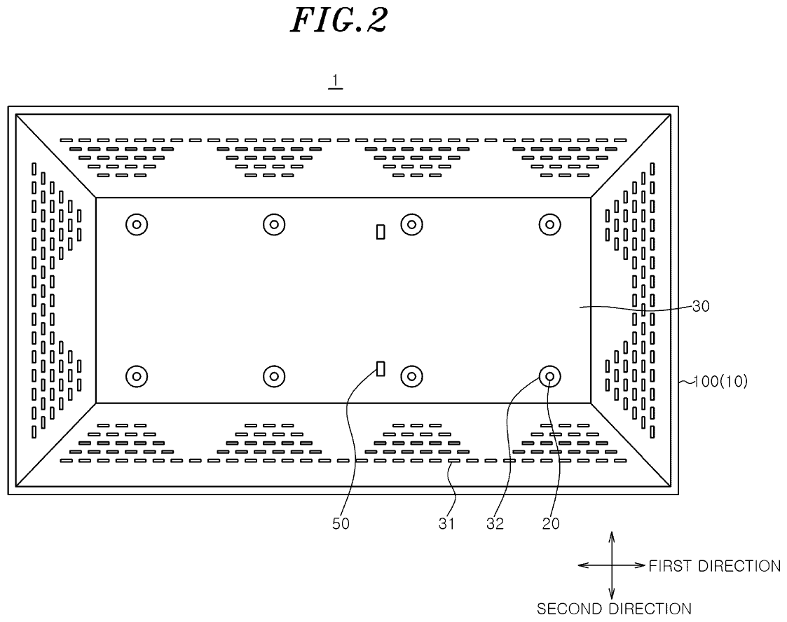

Referring now to FIG. 2, the reflection sheet 30 may reflect light emitted from the plurality of light emitting devices 20. The reflection sheet 30 may be formed in a shape corresponding to the first substrate 100. In other words, the reflection sheet 30 may include a region corresponding to the main body 110 (hereinafter referred to as a sheet body) and a region corresponding to the inclined portion 120 (hereinafter referred to as a sheet inclined portion). The sheet inclined portion may be arranged to be tilted with respect to the sheet body according to the shape of the first substrate 100. Additionally, the reflection sheet 30 may include a sheet hole 31 and a device hole 32.

The sheet hole 31 may be formed to allow a fluid to pass through. Through the sheet hole 31, the fluid between the reflection sheet 30 and the diffusion sheet 40 may flow into the space between the reflection sheet 30 and the substrate assembly 10, and into the plurality of grooves 140. The sheet hole 31 may be formed in a plurality and may be provided in one or more of the sheet body and the sheet inclined portion.

The device hole 32 is a hole through which the light emitting device 20 may pass. The lens 25 of the light emitting device 20 may be disposed between the reflection sheet 30 and the diffusion sheet 40 by the device hole 32. The device hole 32 may be formed in the sheet body.

The diffusion sheet 40 may diffuse the light emitted from the plurality of light emitting devices 20. The diffusion sheet 40 may be disposed above the plurality of light emitting devices 20 and the reflection sheet 30.

The spacer 50 may be disposed between the diffusion sheet 40 and the reflection sheet 30 to maintain a predetermined distance between the diffusion sheet 40 and the reflection sheet 30. The spacer 50 may be made of a material that reflects or transmits the light emitted from the light emitting device 20. The spacer 50 may be connected to and fixed to either the diffusion sheet 40 or the reflection sheet 30. In addition, the spacer 50 may include a material that reflects light or have a surface coated with a material that reflects light. Such a spacer 50 may have a cylindrical or horn shape, for example, extending between the diffusion sheet 40 and the reflection sheet 30.

The bridge line 60 may be connected to the controller 70 and the second substrate 200 to cause the plurality of light emitting devices 20 to generate light. The bridge line 60 may pass through the second hole 110b of the first substrate 100 to connect the second substrate 200 and the controller 70. The bridge line 60 may include an electrically conductive material and an insulating material that covers or surrounds a portion of the electrically conductive material. In cross section, the bridge line 60 may include a hole formed within the insulating material, with the electrically conductive material placed inside the hole. The maximum diameter of the hole can be larger than the maximum diameter of the electrically conductive material and smaller than the maximum diameter of the insulating material. Additionally, the cross sectional thickness of the insulating material may be greater than the maximum diameter of the conductive material. Therefore, the insulating material may be effective in protecting the conductive material from the outside.

The controller 70 may control the plurality of light emitting devices 20. The controller 70 may be disposed on the other side of the first substrate 100.

Hereinafter, the operation and effects of the display device 1 according to the first embodiment of the present disclosure will be described.

In the display device 1 according to the first embodiment of the present disclosure, a plurality of grooves are formed on the first substrate 100, allowing the flow path to move along the surface of the first substrate 100. This enables efficient heat dissipation of heat generated from the light emitting device 20.

Further, the hole may be formed in both the first substrate 100 and the second substrate 200, increasing the surface area for heat dissipation, thereby effectively dissipating the heat generated from the light emitting device 20.

Furthermore, since the sheet inclined portion can be disposed to be tilted with respect to the sheet body, light is more effectively reflected from the sheet inclined portion, resulting in more uniform light reflection. Therefore, the display device 1 of the present disclosure has the effect of enhancing the surface light emission effect.

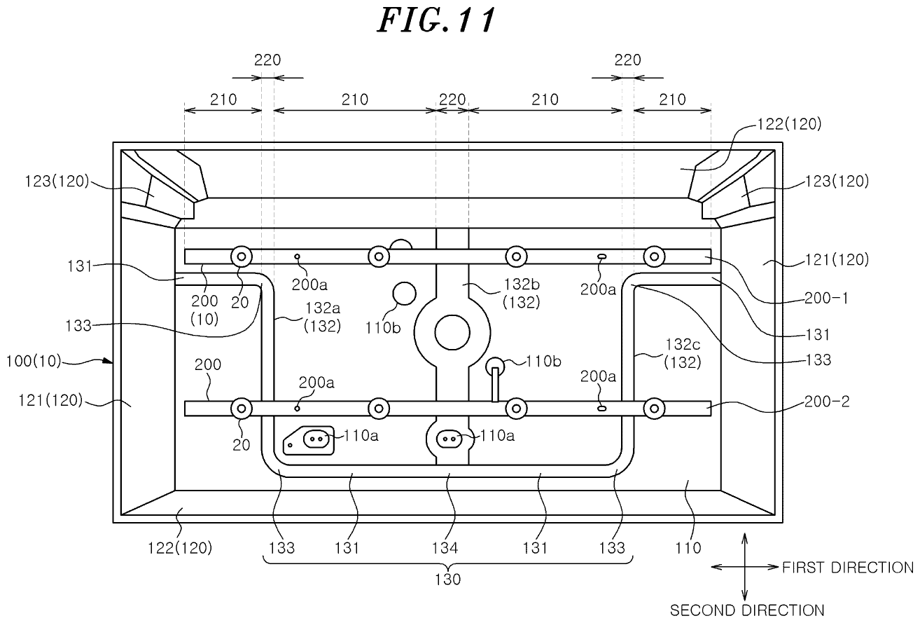

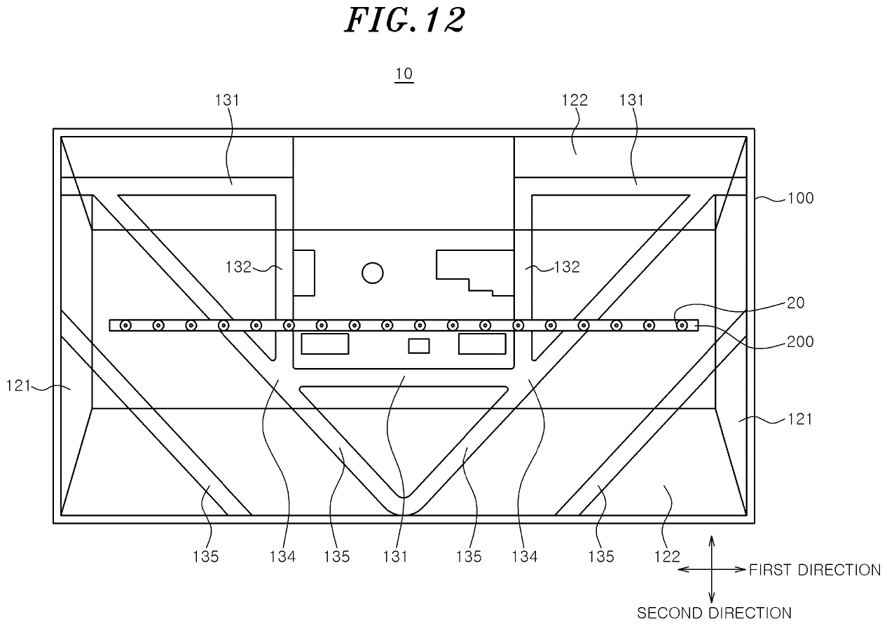

Hereinafter, with reference to FIG. 11, a display device 1 according to a second embodiment of the present invention will be described.

In describing the second embodiment, there is a difference in that the overlapping region of one of the plurality of second substrates 200 is formed differently from the overlapping region of another of the plurality of second substrates 200. This difference will be explained in detail.

In the second embodiment, the first substrate 100 may have the size and number of grooves formed differently depending on the position of the second substrate 200.

The plurality of second substrates 200 may include a first device substrate 200-1 and a second device substrate 200-2.

The area of the overlapping region positioned under the first device substrate 200-1 may differ from the area of the overlapping region positioned under the second device substrate 200-2.

Further, the first device substrate 200-1 may be supported on the first substrate 100 without the contact region 210. In other words, the first device substrate 200-1 may not have an overlapping region.

The second device substrate 200-2 may be disposed on the first substrate 100 such that the area of the overlapping region thereof is larger than the area of the overlapping region of the first device substrate 200-1.

Hereinafter, the operation and effects of the display device 1 according to the second embodiment of the present disclosure will be described.

In the display device 1 according to the second embodiment of the present disclosure, the size and number of the plurality of grooves 140 in the first substrate 100 may be formed differently depending on the position of the second substrate 200, allowing for efficient heat dissipation considering the positions of the plurality of second substrates 200.

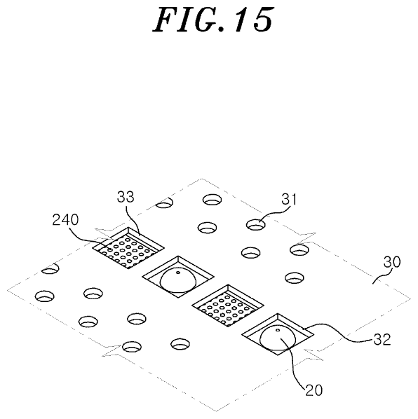

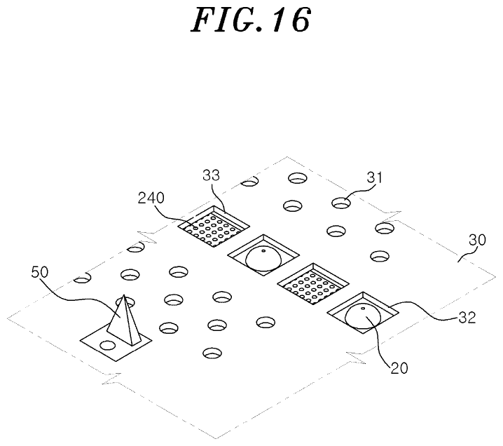

Hereinafter, with reference to FIGS. 12 to 16, the display device 1 according to a third embodiment of the present disclosure will be described. In explaining the second embodiment, there is a difference in that the plurality of grooves 140 may further include a third groove 135, and this difference will be explained in detail.

The third groove 135 may extend in a different direction from the first groove 131 and the second groove 132. The third groove 135 may be formed to be tilted with respect to the first groove 131 and the second groove 132. The third groove 135 may be referred to as an extension groove. A plurality of third grooves 135 may be formed. Some of the third grooves 135 may be inclined at different angles with respect to the first groove 131 and the second groove 132. Additionally, any one of the third grooves 135 may be connected to the first groove 131 and the second groove 132, or to the branch groove 134, allowing communication with the first groove 131 and the second groove 132. Furthermore, the plurality of third grooves 135 may extend in different directions.

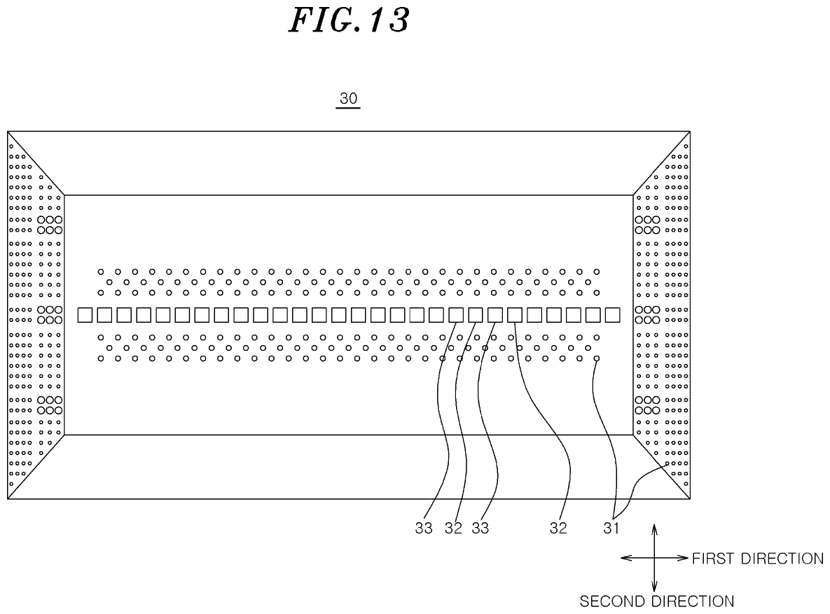

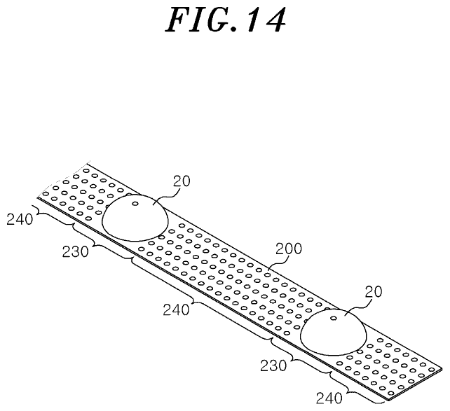

Referring to FIG. 13, the reflective sheet 30 of the display device 1 according to the embodiment of the present disclosure will be described. The reflective sheet 30 may reflect light generated from the plurality of light emitting devices 20. The reflective sheet 30 may be formed in a shape corresponding to the first substrate 100. In other words, the reflective sheet 30 may include a region corresponding to the main body 110, referred to as the sheet body, and a region corresponding to the inclined portion 120, referred to as the sheet inclined portion. The sheet inclined portion may be inclined with respect to the sheet body according to the shape of the first substrate 100. Additionally, the reflective sheet 30 may include sheet the sheet hole 31 and the device hole 32.

The sheet hole 31 may be formed to allow a fluid to pass through. Through the sheet hole 31, the fluid between the reflection sheet 30 and the diffusion sheet 40 may flow into the space between the reflection sheet 30 and the substrate assembly 10, and into the plurality of grooves 140. The sheet hole 31 may be formed in a plurality and may be provided in one or more of the sheet body and the sheet inclined portion.

The device hole 32 is a hole through which the light emitting device 20 may pass. The lens 25 of the light emitting device 20 may be disposed between the reflection sheet 30 and the diffusion sheet 40 by the device hole 32. The device hole 32 may be formed in the sheet body.

The reflective sheet 30 may have pattern holes 33 formed therein. The pattern holes 33 may be formed in a plurality in the sheet body. For example, a plurality of pattern holes 33 may be arranged in one direction at the center of the sheet body. Additionally, the plurality of pattern holes 33 may be located between the device holes 32. Through the plurality of pattern holes 33, one or more patterns in a pattern region 240 may be exposed to the outside without being covered by the reflective sheet 30.

Referring to FIGS. 14 to 16, the second substrate 200 of the display device 1 according to the embodiment of the present disclosure will be described. A device region 230 may be a region on the second substrate 200 where the light emitting device 20 is placed. This device region 230 may be defined as a region projected by the light emitting device 20 onto the second substrate 200. The device region 230 may be formed in a plurality corresponding to the number of light emitting devices 20. The plurality of device regions 230 may be spaced apart from each other on one surface of the second substrate 200.

The pattern region 240 may be located between the plurality of device regions 230 and provide patterns with a reflectance different from that of the surface of the second substrate 200. In other words, one or more patterns may be placed in the pattern region 240, which may not overlap with the plurality of device regions 230. The pattern may be formed in a circular shape, but it is not limited thereto. The pattern region 240 may have a lower light reflectance than the surface of the second substrate 200 where no pattern is present. One or more patterns in the pattern region 240 may be exposed to the outside through the pattern hole 33. Meanwhile, one or more patterns may also be formed in the device region 230 and may be exposed to the outside through the device hole 32. The one or more patterns may be formed on the surface of the second substrate 200 by any suitable method for modifying the reflectance thereof. The one or more patterns may be formed through printing.

Further, some of the plurality of sheet holes 31 may be formed in the sheet body and arranged along the direction where the pattern hole 33 and the device hole 32 are aligned. Furthermore, some of the sheet holes 31 formed in the sheet body may be located between the pattern hole 33 and the spacer 50. Also, between the plurality of sheet holes 31 formed in the sheet body, the pattern hole 33 and device hole 32 may be disposed.

Therefore, at least a portion of the pattern region 240 is not covered by the reflective sheet 30 through the pattern hole 33, reducing light reflection at the center of the reflective sheet 30 caused by the patterns. As a result, light can be reflected more uniformly, improving the surface light emitting effect of the display device 1.

Further examples of the invention are as follows:
Example 1: A light emitting module assembly comprising: a first substrate (100) including a groove (130); and a second substrate (200) disposed on the first substrate (100) and extended in a first direction to support a plurality of light emitting devices (20), wherein the second substrate (200) includes a contact region (210) contacting with the first substrate (100) and an overlap region (220) overlapped with the groove in a thickness direction. In a light emitting module assembly according to example 1, the overlap region of the second substrate can get in touch with air in the groove for improved cooling, so that reliability of the light emitting devices can be improved.
Example 2: A light emitting module assembly comprising: a first substrate (100) including a groove (130); and a second substrate (200) disposed on the first substrate (100) and extended in a first direction to support a plurality of light emitting devices (20), wherein the groove (130) includes a first groove (131) extending parallel to the first direction, and a second groove (132) extending in a direction that is different from the first direction. In a light emitting module assembly according to example 2, air can flow through the grooves in various directions, so that a cooling efficiency can be improved.
Example 3: A light emitting module assembly comprising: a first substrate (100) including a groove (130); and a plurality of second substrates (200) disposed on the first substrate (100) and extended in a first direction to support a plurality of light emitting devices (20), wherein one of the second substrates (200) includes an overlap region (220) overlapped with the groove in a thickness direction, and another one of the second substrates (200) includes an overlap region (220) overlapped with the groove in a thickness direction, and an area of the overlap region (220) of the one of the second substrate (200) is different with an area of the overlap region (220) of the another one of the second substrate (200). In a light emitting module assembly according to example 3, the overlap region can be varied between different second substrates, allowing adjustment of the cooling effect depending on the position of the second substrate.
Example 4: A light emitting module assembly comprising: a first substrate (100) including a groove (130); and a second substrate (200) disposed on the first substrate (100) and extended in a first direction to support a plurality of light emitting devices (20), wherein the groove (130) includes a first groove (131) extending parallel to the first direction and a second groove (132) extending in second direction that is perpendicular to the first direction and a branching groove (134) extending and crossing to the first groove(131) and the second groove(132). In a light emitting module assembly according to example 4, the branching groove may connect first and second grooves, allowing for better circulation of air in the first and second grooves.
Example 5: A light emitting module assembly comprising: a first substrate (100); a second substrate (200) disposed on the first substrate (100) and extended in a first direction to support a plurality of light emitting devices (20); and a reflective sheet (30) disposed on the first substrate (100), wherein the reflective sheet (30) includes device holes (32) formed to corresponding to the light emitting devices (20) and sheet holes (31) formed on an inclined region of the reflective sheet (30) and periphery to the device holes (32). In a light emitting module assembly according to example 5, a light intensity in periphery region of the light emitting device can be decreased, so the difference of the intensity between the periphery region and the inclined region can be decreased.
Example 6: A light emitting module assembly comprising: a first substrate (100); and a second substrate (200) disposed on the first substrate (100) and extended in a first direction to support a plurality of light emitting devices (20), wherein the second substrate (200) includes a pattern region (240) between the light emitting devices (20), and the pattern region (240) includes a plurality of circles. In a light emitting module assembly according to example 6, light can disperse uniformly at a region between the light emitting devices. In particular, a circle pattern not having any sharp or right angles, uniform and smooth dispersion can be obtained.
Example 7: A light emitting module assembly comprising: a first substrate (100); a second substrate (200) disposed on the first substrate (100) and extended in a first direction to support a plurality of light emitting devices (20); and a reflective sheet (30) disposed on the first substrate (100), wherein the reflective sheet (30) includes device holes (32) formed to corresponding to the light emitting devices (20) and pattern holes (33) exposing a portion of the second substrate (200). In a light emitting module assembly according to example 7, the pattern holes allow adjustment of a light intensity of a region between light emitting devices, so an intensity at the region is less than sum of intensity of light emitting devices both side of the region.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

### EXPLANATION OF REFERENCE NUMERALS

1: display device
10: substrate assembly
20: light emitting device
21: light emitting diode chip
22: molding portion
23: electrode
24: housing
25: lens
30: reflective sheet
31: sheet hole
32: device hole
33: pattern hole
40: diffusion sheet
50: spacer
60: bridge line
70: controller
100: first substrate
110: main body
110a: first hole
110b: second hole
120: inclined portion
121: first side inclined portion
122: second side inclined portion
123: auxiliary inclined portion
130: groove
131: first groove
132: second groove
132a: first groove portion
130a: groove bottom surface
132b: second groove portion
130b: groove side surface
133: curved groove
132c: third groove portion
134: branch groove
135: third groove
200: second substrate
200a: hole
210: contact region
220: overlapping region
230: device region
240: pattern region

1. A substrate assembly comprising:
a first substrate having a plurality of grooves formed on one surface; and
a second substrate extending in one direction to support a plurality of light emitting devices and supported on the one surface of the first substrate,
wherein the plurality of grooves include:
a first groove extending in a direction parallel to the one direction; and
a second groove extending in a direction deviating from the first groove.

2. The substrate assembly of claim 1, wherein the second groove partially overlaps with the second substrate in a thickness direction of the second substrate.

3. The substrate assembly of claim 2, wherein the second substrate includes:
a contact region in contact with the first substrate; and
an overlapping region overlapping with the second groove in the thickness direction of the second substrate, and
wherein an area of the contact region is larger than an area of the overlapping region.

4. The substrate assembly of claim 3, wherein the second substrate is supported on the first substrate such that the contact region and the overlapping region alternate in the one direction.

5. The substrate assembly of claim 1, wherein each of the plurality of grooves includes:
a groove bottom surface; and
a plurality of groove side surfaces inclined with respect to the groove bottom surface, and
wherein the groove bottom surface is disposed between the plurality of groove side surfaces.

6. The substrate assembly of claim 1, wherein a thickness of the first substrate and a thickness of the second substrate are different from each other.

7. The substrate assembly of claim 1, wherein the plurality of grooves further includes a curved groove connecting the first groove and the second groove.

8. The substrate assembly of claim 1, wherein the plurality of grooves further includes a third groove extending in a direction different from the first groove and the second groove.

9. The substrate assembly of claim 1, wherein the second groove includes a plurality of second grooves, and
wherein a width of one of the plurality of second grooves is different from a width of another of the plurality of second grooves.

10. The substrate assembly of claim 1, wherein the second groove includes a plurality of second grooves, and
wherein a depth of one of the plurality of second grooves is different from a depth of another of the plurality of second grooves.

11. The substrate assembly of claim 3, wherein the second substrate includes a plurality of second substrates, and
wherein an area of the overlapping region of one of the plurality of second substrates is different from an area of the overlapping region of another of the plurality of second substrates.

12. The substrate assembly of claim 1, wherein one or more holes are formed in at least one of the first substrate and the second substrate.

13. The substrate assembly of claim 1, wherein the first substrate includes:
a main body for supporting the second substrate; and
a plurality of inclined portions disposed at an edge of the main body and inclined with respect to the main body, and
wherein the plurality of inclined portions include:
a plurality of first side inclined portions disposed at the edge of the main body and spaced apart from each other in the one direction; and
a plurality of second side inclined portions disposed at the edge of the main body and spaced apart from each other in another direction perpendicular to the one direction, and
wherein the first side inclined portion and the second side inclined portion are inclined at different angles with respect to the main body.

14. The substrate assembly of claim 13, wherein the plurality of inclined portions further include:
an auxiliary inclined portion disposed between the first side inclined portion and the second side inclined portion and inclined at an angle different from the angles of the first side inclined portion and the second side inclined portion.

15. A substrate assembly comprising:
a first substrate having a plurality of grooves formed on one surface; and
a second substrate extending in one direction to support a plurality of light emitting devices and supported on the one surface of the first substrate,
wherein the plurality of grooves includes:
a groove portion extending in a direction perpendicular to the one direction; and
an extension groove extending in a direction deviating from the groove portion.

16. A display device comprising:
a plurality of light emitting devices that generate light;
a substrate assembly supporting the plurality of light emitting devices; and
a reflective sheet supported on the substrate assembly and reflecting the light emitted from the plurality of light emitting devices,
wherein the substrate assembly includes:
a first substrate having a plurality of grooves formed on one surface; and
a second substrate extending in one direction to support the plurality of light emitting devices and supported on the one surface of the first substrate,
and at least some of the plurality of grooves extend in different directions.

17. The display device of claim 16, wherein the second substrate includes:
a plurality of device regions in which the plurality of light emitting devices are respectively disposed; and
a pattern region located between the plurality of device regions and having one or more patterns with a reflectance different from a surface of the second substrate.

18. The display device of claim 17, wherein the reflective sheet includes a plurality of holes, and
wherein at least one of the plurality of holes is formed at a position where one or more patterns in the pattern region are exposed to an outside.

19. The display device of claim 17, further comprising:
a diffusion sheet diffusing light emitted from the plurality of light emitting devices; and
a spacer disposed between the reflective sheet and the diffusion sheet,
wherein the spacer reflects light emitted from the plurality of light emitting devices.

20. The display device of claim 17, further comprising:
a controller supported on another surface opposite to the one surface of the first substrate and configured to control the plurality of light emitting devices; and
a bridge line electrically connecting the controller and the plurality of light emitting devices,
wherein the first substrate includes a second hole through which the bridge line passes, and
wherein the plurality of grooves include:
a plurality of groove portions extending in a direction perpendicular to the one direction and spaced apart from each other in the one direction, and
wherein the second hole is located between the plurality of groove portions.
